(19) United States
(12) Patent Application Publication
(10) Pub. No.: US 2011/0204881 A1
(43) Pub. Date: Aug. 25, 2011

(54) ZERO POSITIONING FOR SENSOR

(75) Inventors: Joachim Spratte, Osnabruck (DE); Katharina Matzold, Bohmte (DE); Holger Hoppner, Steinfeld (DE)

(73) Assignee: ZF FRIEDRICHSHAFEN AG, Friedrichshafen (DE)

(21) Appl. No.: 13/060,500

(22) PCT Filed: Aug. 11, 2009
(86) PCT No.: PCT/DE2009/050044

§ 371 Date: May 11, 2011

(30) Foreign Application Priority Data
Aug. 28, 2008 (DE) 10 2008 041 634.7

(51) Int. Cl. H01L 43/06; G01B 7/14; H01L 43/08

(52) U.S. Cl. 324/207.2; 324/207.13; 324/207.21

(57) ABSTRACT

An arrangement to establish a zero position for a sensor that serves to detect movement between parts of a technical system that are connected by a ball joint. The arrangement comprising a joint housing of the ball joint rigidly connected to a first part of the system, a ball pin rigidly connected to a second part of the system, and a sensor for detecting the movements of the ball pin. At least a first sensor element is disposed on the ball pin and a second sensor element is disposed on a part of the system that is immovable with respect to the joint housing. An axial area of the lateral surface of the ball pin is flattened and positively locks an inner contour of the mounting eye or a disk-shaped element which abuts the mounting eye and is fixed by positively locking with the second part of the system.

This application is a national stage completion of PCT/DE2009/050044 filed Aug. 11, 2009 which claims priority from German Application Serial No. 10 2008 041 634.7 filed Aug. 28, 2008.

### FIELD OF THE INVENTION

The invention relates to an arrangement with a sensor that is designed to establish a zero position of the relevant sensor serving to detect deflection movements, and to position the sensor in this zero position. It also relates to an arrangement for detecting deflections in a ball joint that serves for mounting parts of a technical system, preferably parts of a motor vehicle chassis.

### BACKGROUND OF THE INVENTION

Ball joints are used, in many instances, in parts that move with respect to each other in chassis of motor vehicles. Such ball joints consist of a ball pin having a ball in a joint shell or joint housing that can move in a plurality of directions. The corresponding ball pin is an at least approximately axially symmetrical part consisting of a substantially cylindrical pin, at one end of which is formed the ball to be received in the joint housing. The end of the pin opposite the ball is generally provided with a thread that is guided through an opening in a chassis part provided therefore such as a wheel carrier, and is screwed to this chassis part by means of a nut. With modern motor vehicles, it is known to detect the deflection of the ball pin in the joint housing by means of suitable sensors. This serves for example to detect the alignment of a suspension arm of a chassis axle and/or to detect the inclination of the vehicle body. Based on the detection of these location parameters, servomotors for example are actuated for automatically adjusting the height of the headlamps and/or for an adaptive cornering light.

To be able to detect corresponding deflection angles, a zero position must be defined for the elements of the sensor comprising at least one transmitter element and at least one reference element as a basis of reference for measurement. That is, the elements forming the sensor that are arranged on the ball pin on the one hand and on a chassis part on the other hand must be positioned in a specific position with respect to each other which represents a zero position for measurement.

A ball pin of a ball joint is known from DE 197 48 117 A1 having an oval cross-sectional area in a middle section of the pin. In conjunction with an elongated or elliptical penetration in a chassis part for feeding through and fastening the ball pin, the design of the ball pin described in the document serves to form a lock against rotation. The aim thereof is to keep the pin from rotating in the corresponding penetration of the chassis part when screwing tight or loosening the nut for fastening it. By preventing the pin from rotating in the penetration, the nut can be tightened or loosened in the penetration without having to hold the counterpart, i.e., the ball pin, with a tool. However, unique positioning of the ball pin with the goal of establishing a zero position for a sensor is not thereby achieved since the elliptical part of the ball pin can be arranged in the slot for feeding it through in at least two different positions offset from each other by 180°. In addition, it is more involved from a production point of view to design a slot instead of a round hole in the part of the chassis provided for feeding through the pin.

### SUMMARY OF THE INVENTION

The object of the invention is to provide an arrangement for establishing a specific zero position, and to position a sensor detecting the deflections of a ball joint. Preferably, the corresponding arrangement should also be designed so that it is easy to realize from a production point of view.

The arrangement to establish a zero position for measuring the deflection movements of a ball joint that connects together parts of a mechanical system, preferably parts of a motor vehicle chassis, consists of a joint housing of the ball joint rigidly connected to a first part of the system, a ball pin rigidly connected to a second part of the system, and a sensor detecting the deflection movements of the ball pin in the joint housing having at least two sensor elements that complement each other. One of the aforementioned sensor elements is arranged on the ball pin, and one is arranged on the part of the system equipped with the ball joint being immovable with respect to the joint housing. The ball pin moves in the joint housing of the ball joint designed in a known manner by means of its joint ball disposed on one of its axial ends, and it is releasably attached by means of its axial end opposite the joint ball to an mounting eye of the part connected to it. The aforementioned axial end of the ball pin thereby projects through the mounting eye serving to fasten it.

According to the invention, the lateral surface of the ball pin that otherwise has a circular cross section is flattened in an axial area, and this flattened area is brought into positive locking with a correspondingly designed inner contour of the mounting eye or a disk-shaped element. In the last-mentioned instance in which the flattened area of the ball pin is brought into engagement with the correspondingly designed inner contour of a disc-shaped element, the relevant disk-shaped element abuts the mounting eye and is itself fixed in a predetermined position with respect to the peripheral direction of the ball pin by a positive locking of its outer contour with the part connected to the ball pin. The flattened axial area formed on the ball pin according to the invention is preferably realized in that the ball pin has a straight peripheral section in this area.

As already mentioned, the flattened area of the ball pin can be brought directly into a positive locking with the mounting eye of the part to be connected to the ball pin or with an additionally provided disk-shaped element depending on the embodiment of the invention. However, in view of the fact that the formation of a non-round mounting eye, i.e. preferably having a straight section on its inner contour, is comparatively complex from a production point of view, the second variation would be preferable. In a correspondingly designed embodiment of the arrangement according to the invention, the ball pin has a thread on its end facing away from the joint ball by means of which it is screwed, with the aid of a nut, into the mounting eye of the part to be connected to it at its side facing away from the joint ball. On this side of the mounting eye which is circular in this case, a recess is formed with a groove running radially outward. A washer, inserted in the recess, is disposed between the mounting eye and a nut for the threaded connection of the ball pin and has an inner contour designed to correspond with the flattened peripheral contour of the ball pin. On its peripheral contour, the aforementioned washer has a projection, which engages in the groove, pointing radially outward, formed in this embodiment in the recess of the mounting eye. On the one hand, the ball pin is thereby brought into a positive locking with the inner contour of the washer, whereas on the other hand, the outer contour of the washer is brought into a positive locking with the part rigidly connected to the ball pin, for example the wheel carrier of a motor vehicle.

By means of this dual positive locking, the ball pin cannot move independently about its longitudinal axis when fastened to the mounting eye, nor can it execute such a movement together with the washer. The groove formed in the recess of the mounting eye and the projection of the washer engaged therein are of course disposed in a specific position. The specific position of the projection formed on the outer contour is provided by its fixed position relative to the straight section of the inner contour of the washer. Given the thereby fixed position of this straight section with respect to the peripheral direction and the flattening of the ball pin corresponding to this contour section, the ball pin is also fixed in a specified position with respect to the peripheral direction when fastened to the mounting eye. Since one of the sensor elements is disposed on the ball pin, a reference position is thereby simultaneously provided for measuring the deflection movements of the ball joint and the parts of the corresponding mechanical system fastened thereto, for example the chassis of a motor vehicle.

According to one possible embodiment of the invention, the sensor serving to measure the deflection movement is realized by means of at least one magnetoresistive element. The sensor is however preferably formed by a permanent magnet and at least one Hall element. In one corresponding embodiment of the invention, the permanent magnet in the joint ball is disposed on its free pole, whereas the part opposite this pole rigidly connected to the joint housing is disposed on at least one Hall element. By evaluating the Hall voltage generated in at least one Hall element when the ball pin moves, the directions and angles of the deflection movements of the ball pin within the joint housing can be determined. The sensor is preferably formed with a triaxial Hall element or a plurality of Hall elements. In addition, the pole of the joint ball and the permanent magnet disposed thereupon are preferably covered with a cover comprising a nonmagnetic material for protection from contaminants.

### BRIEF DESCRIPTION OF THE DRAWINGS

Details of the arrangement according to the invention will be explained once again below with reference to an embodiment. The associated drawings show:

FIG. 1: a sectional view of a possible embodiment of the arrangement according to the invention,

FIG. 2a: The ball pin of the arrangement according to FIG. 1,

FIG. 2b: the ball pin according to FIG. 2a in a longitudinal section following line 2b-2b,

FIG. 2c: the ball pin according to FIG. 2a in a section following line 2c-2c,

FIG. 3: the washer used to fasten the ball pin in the arrangement according to FIG. 1,

FIG. 4a: an enlarged detail of the arrangement with a top view of the face of the ball pin,

FIG. 4b: a section of the detail according to FIG. 4a with a section following line 4b-4b.

### DETAILED DESCRIPTION OF THE DRAWINGS

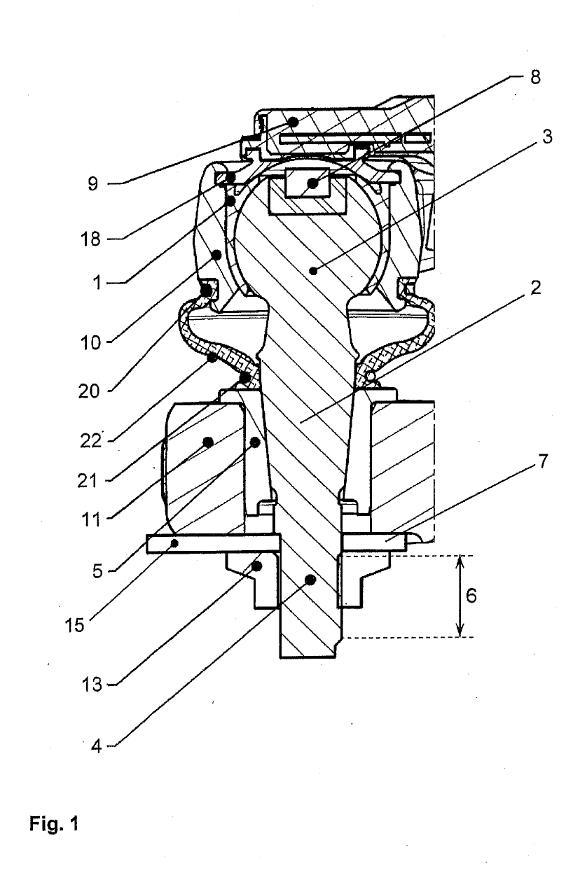

FIG. 1 shows a sectional view of a possible embodiment of the arrangement according to the invention. This is formed for example, as a component of the chassis of a motor vehicle in which a control arm of the chassis is mounted via a ball joint 1, 2, 3 on a wheel carrier. The arrangement consists of the bearing shell 1 disposed in part 10, i.e., the control arm of the system or chassis equipped with the ball joint, and rigidly connected thereto, and ball pin 2, 3 formed in a well-known manner having a side facing away from the bearing shell or the joint ball engaged therewith that is screwed to a second part 11 of the system, such as a wheel carrier, using a washer 7 formed according to the invention. In this context, the ball pin 2, 3 projects through an mounting eye 5 formed in the wheel carrier and realized by a steel insert. As a part of the sensor 8, 9, a permanent magnet 8 is disposed at the free pole 17 of the joint ball 3 formed at an axial end of the ball pin 2, 3. A sensor module formed by preferably a plurality of Hall elements 9 (not shown) also belongs to the sensor 8, 9. This is disposed in the part 10 of the chassis which is immovable with respect to the joint housing 1 or received in the joint housing 1. By rotating the ball pin 2, 3 or the joint ball 3 formed thereupon in the joint housing 1, the permanent magnet 8 arranged on the joint ball 3 has respectively different positions relative to the Hall elements of the sensor module in a rigid arrangement with respect to the joint housing 1. Different Hall voltages are thereby generated in the Hall elements 9, the evaluation of which enabling the determination of the relative position of the sensor part disposed on the ball pin 2, 3, i.e., the permanent magnet 8, with respect to the Hall elements 9 and hence the direction and angle of the respective deflection movements of the ball joint 2, 3. The joint ball 3 and the permanent magnet 8 disposed thereupon are covered with a sealing cover 18 consisting of a nonmagnetic material for protection from contaminants. The ball joint 1, 2, 3 is protected from contaminants by a bellows seal 22 fastened to the ball pin by means of clamping rings 20, 21.

The washer 7 used together with the nut 13 for the threaded connection of the ball pin 2, 3 has a projection 15 according to the invention on its outer contour. The washer 7 is disposed in a recess 14 formed in the mounting eye 5 between the nut 13 and the mounting eye 5 and, by means of its projection 15, is brought into engagement with a groove 16 directed radially outward in the mounting eye 5 or the recess 14. The washer 7 is thereby disposed in a specific position relative to the peripheral direction u of the ball pin 2, 3 and is immovable with respect to the peripheral direction u due to the resulting positive engagement with the groove 16.

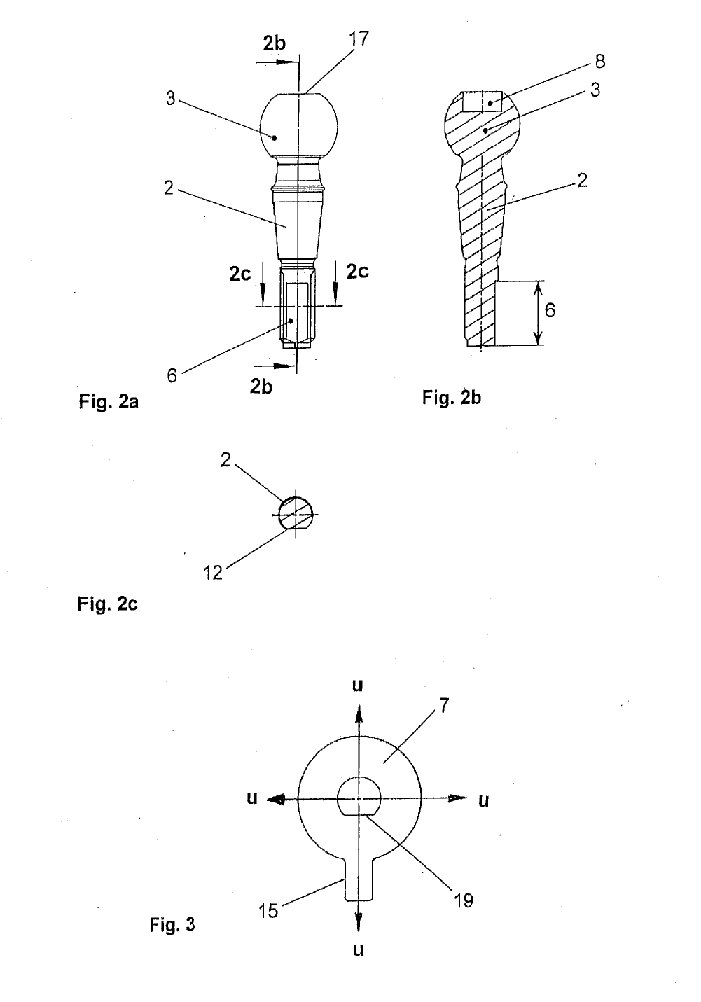

FIGS. 2a to 2c again portray the ball pin 2, 3 from the arrangement according to FIG. 1 in different views. FIG. 2a shows a spatial representation of the ball pin 2, 3 with the joint ball 3 disposed on one of its axial ends with its pole 17. FIG. 2b which again displays a longitudinal section of the ball pin 2, 3 following line 2b-2b reveals that the axial end 4 of the ball pin 2, 3 to be guided through the mounting eye 5 has a flattening. As can be seen in FIG. 2c which displays a section of the ball pin 2, 3 following line 2c-2c, a straight peripheral section 12 is formed on the otherwise circular cross-sectional surface of the ball pin 2, 3 in the corresponding flattened area 6. After being guided through the mounting eye 5, the flattened area 6 is brought into engagement with the corresponding inner contour of the washer 7 to be disposed between the nut 13 used for the threaded connection and the mounting eye 5 while connecting to the wheel carrier 11.

The design of the corresponding washer 7 is again illustrated in FIG. 3. Here it can be seen that a straight peripheral section 19 corresponding with the flattened area 6 of the ball pin 2, 3 is formed in the otherwise also circular inner contour of the washer. At the height of this straight peripheral section 19 of the inner contour, a projection 15 extending radially outward is formed on the outer contour for becoming engaged with the groove 16 formed in the recess 14 of the mounting eye 5 on the wheel carrier 11.

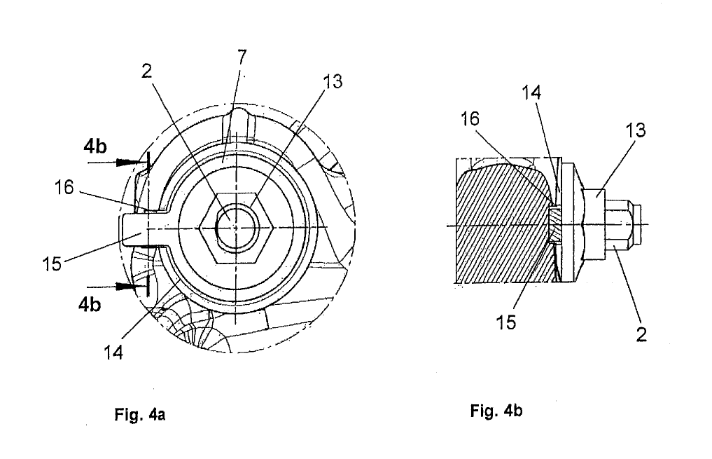

FIG. 4a shows an enlarged detail of the previously portrayed arrangement in a top view of the face of the end of the ball pin 2, 3 opposite the joint ball 3. The parts of the screw connection realized with the nut 13 (a flanged nut in the example) and the washer 7 can be easily seen here, and especially the recess 14 in the mounting eye 5 as well as the groove 16 extending radially outward in the area of the recess 14 in which the projection 15 of the washer 7 engages. FIG. 4b again shows a section of the detail according to FIG. 4a in a section following line 4b-4b.

### LIST OF REFERENCE CHARACTERS

1 bearing shell

2, 3 ball pin

3 joint ball

4 Axial end

5 Mounting eye

6 Flattened area

7 Disc-shaped element, washer

8 Sensor element, such as a (permanent) magnet

9 Sensor element, Hall element(s), for example

10, 11 Part

12 Peripheral section

13 Nut

14 Recess

15 Projection

16 Groove

17 Pole

18 Sealing cover

19 Peripheral section

20, 21 Clamping ring

22 bellows seal

1-7. (canceled)

8. An arrangement having a sensor (8, 9) to establish a zero position for measuring a deflection movement of a ball joint (1, 2, 3) that connects together parts of a mechanical system, the arrangement comprising:
a joint housing (1) being rigidly connected to a first part (10) of the mechanical system,
a ball pin (2, 3) being rigidly connected to a second part (11) of the mechanical system and moving with a joint ball (3), disposed adjacent one of its axial ends, within the joint housing (1),
the sensor (8, 9), for detecting the deflection movement, comprising at least two sensor elements that complement one another with one of the at least two sensor elements being arranged on the ball pin (2, 3), and the other of the at least two sensor elements being arranged on the part of the mechanical system equipped with the ball joint (1, 2, 3) immovable with respect to the joint housing (1),
an axial end (4) of the ball pin (2, 3), opposite the joint ball (3), projecting through a mounting eye (5) of a part releasably connected thereto, a lateral surface of the ball pin (2, 3) that otherwise has a circular cross section is flattened in an axial area (6), and
the flattened area (6) being brought into positive locking with a correspondingly designed inner contour of one of the mounting eye (5) and a disk-shaped element (7) that abuts against the mounting eye (5), and is itself fixed in a predetermined position with respect to a peripheral direction (u) of the ball pin (2, 3) by a positive locking of its outer contour with the part connected to the ball pin (2, 3).

9. The arrangement according to claim 8, wherein the ball pin (2), in the flattened axial area (6), comprises a straight peripheral section (12).

10. The arrangement according to claim 8, wherein the ball pin (2, 3) has a thread on the axial end (4) opposite the joint ball (3) by which the ball pin (2, 3) is secured, via a nut (13), to the mounting eye (5) of the second part (11) on a side facing away from the joint ball (3), on this side of the circular mounting eye (5), a recess (14) is formed with a groove (16) extending radially outward, and a washer (7) is inserted in the recess (14) and is disposed between the mounting eye (5) and the nut (13) has an inner contour formed to correspond with the flattened peripheral contour of the ball pin (2, 3) which engages by a projection (15) formed on its peripheral contour in the groove (16) formed in the recess (14).

11. The arrangement according to claim 8, wherein the sensor (8, 9) comprises at least one magnetoresistive element.

12. The arrangement according to claim 8, wherein the sensor (8, 9) comprises at least one Hall element (9) and one magnet (8).

13. The arrangement according to claim 12, wherein the magnet (8) is located at a free pole (17) of the joint ball (3) and the at least one Hall element (9) is arranged on the first part (10) connected to the joint housing (1) and located opposite the free pole (17) of the joint ball (1) such that directions and angles of the deflection movement are determined by evaluating a Hall voltage generated in the at least one Hall element (9) due to the deflection of the ball pin (2, 3) within the joint housing (1).

14. The arrangement according to claim 13, wherein a sealing cover (18) covers the free pole (17) of the joint ball (3), with the magnet (8) arranged thereon.

15. An arrangement to establish a zero position for measuring deflection movement of a ball joint (1, 2, 3) which couples parts of a mechanical system, the arrangement comprising:
a joint housing (1) being rigidly connected to a first part (10) of the mechanical system,
a ball pin (2, 3) being rigidly connected to a second part (11) of the mechanical system,
a first axial end of the ball pin (2, 3) comprising a joint ball (3), being movably secured within the joint housing (1), and a sensor (8, 9) for detecting the deflection movement of the ball joint (1, 2, 3),
the sensor (8, 9) comprising at least a first sensor element (8) being supported on the ball pin (2, 3) and a complimentary second sensor element (9) being rigidly fixed with respect to the joint housing (1),
a second axial end (4) of the ball pin (2, 3), remote from the joint ball (3), projecting through a mounting eye (5) and being releasably connected to the second part (11) of the mechanical system,
an axial portion of the second axial end (4) of the ball pin (2, 3) comprising a flattened area (6) which positively interlocks with a corresponding inner contour of one of the mounting eye (5) and a disk-shaped element (7), that is fixed in a predetermined position with respect to a peripheral direction (u) of the ball pin (2, 3), by positively locking an outer contour of the disk-shaped element (7) with the second part (11) of the mechanical system rigidly connected to the ball pin (2, 3).
